(19) United States
(12) Patent Application Publication
(10) Pub. No.: US 2011/0241020 A1
(43) Pub. Date: Oct. 6, 2011

(54) HIGH ELECTRON MOBILITY TRANSISTOR WITH RECESSED BARRIER LAYER

(75) Inventor: Paul Saunier, Addison, TX (US)

(73) Assignee: TRIQUINT SEMICONDUCTOR, INC., Hillsboro, OR (US)

(21) Appl. No.: 12/751,762

(22) Filed: Mar. 31, 2010

(51) Int. Cl. H01L 29/778; H01L 21/338; H01L 29/205; H01L 29/161

(52) U.S. Cl. 257/77; 438/172; 257/76; 257/194; 257/E21.403; 257/E29.091; 257/E29.084; 257/E29.246

(57) ABSTRACT

Embodiments of a high electron mobility transistor with recessed barrier layer, and methods of forming the same, are disclosed. Other embodiments are also be described and claimed.

### GOVERNMENT INTERESTS

This invention was made with Government support under contract number FA8650-08-C-1443 awarded by the Air Force Research Laboratory. The United States government has certain rights in this invention.

### FIELD

Embodiments of the present disclosure relate generally to the field of high electron mobility transistors (HEMTs), and more particularly to HEMTs with recessed barrier layers.

### BACKGROUND

A high electron mobility transistor (HEMT) is a type of field effect transistor (FET) in which a heterojunction is generally formed between two semiconductor materials of different bandgaps. In HEMTs, high mobility electrons are generally generated using, for example, a heterojunction of a highly-doped wide bandgap n-type donor-supply layer and a non-doped narrow bandgap channel layer with no dopant impurities. Current in a HEMT is generally confined to a very narrow channel at the junction, and flows between source and drain terminals, wherein the current is controlled by a voltage applied to a gate terminal.

In general, a transistor may be classified as a depletion mode transistor or an enhancement mode transistor. In various applications, it may be desirable to have enhancement mode FET devices with relatively high maximum current density, relatively high transconductance, and relatively high breakdown voltage. It may also be desirable to integrate enhancement mode FET devices with depletion mode FET devices.

### BRIEF DESCRIPTION OF THE DRAWINGS

Embodiments are illustrated by way of example and not by way of limitation in the figures of the accompanying drawings, in which like references indicate similar elements and in which:

FIG. 1 schematically illustrates a cross-sectional view of a semiconductor device, in accordance with various embodiments of the present disclosure;

FIG. 2 schematically illustrates a cross-sectional view of another semiconductor device, in accordance with various embodiments of the present disclosure; and

FIG. 3 illustrates a method for fabricating a semiconductor device on a semiconductor substrate, in accordance with various embodiments of the present disclosure.

### DETAILED DESCRIPTION

Various aspects of the illustrative embodiments will be described using terms commonly employed by those skilled in the art to convey the substance of their work to others skilled in the art. However, it will be apparent to those skilled in the art that alternate embodiments may be practiced with only some of the described aspects. For purposes of explanation, specific devices and configurations are set forth in order to provide a thorough understanding of the illustrative embodiments. However, it will be apparent to one skilled in the art that alternate embodiments may be practiced without the specific details. In other instances, well-known features are omitted or simplified in order not to obscure the illustrative embodiments.

Further, various operations will be described as multiple discrete operations, in turn, in a manner that is most helpful in understanding the present disclosure; however, the order of description should not be construed as to imply that these operations are necessarily order dependent. In particular, these operations need not be performed in the order of presentation.

The phrase “in various embodiments” is used repeatedly. The phrase generally does not refer to the same embodiments; however, it may. The terms “comprising,” “having,” and “including” are synonymous, unless the context dictates otherwise.

In providing some clarifying context to language that may be used in connection with various embodiments, the phrases “A/B” and “A and/or B” mean (A), (B), or (A and B); and the phrase “A, B, and/or C” means (A), (B), (C), (A and B), (A and C), (B and C) or (A, B and C).

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled to each other.

In various embodiments, the phrase “a first layer formed on a second layer,” may mean that the first layer is formed over the second layer, and at least a part of the first layer may be in direct contact (e.g., direct physical and/or electrical contact) or indirect contact (e.g., having one or more other layers between the first layer and the second layer) with at least a part of the second layer.

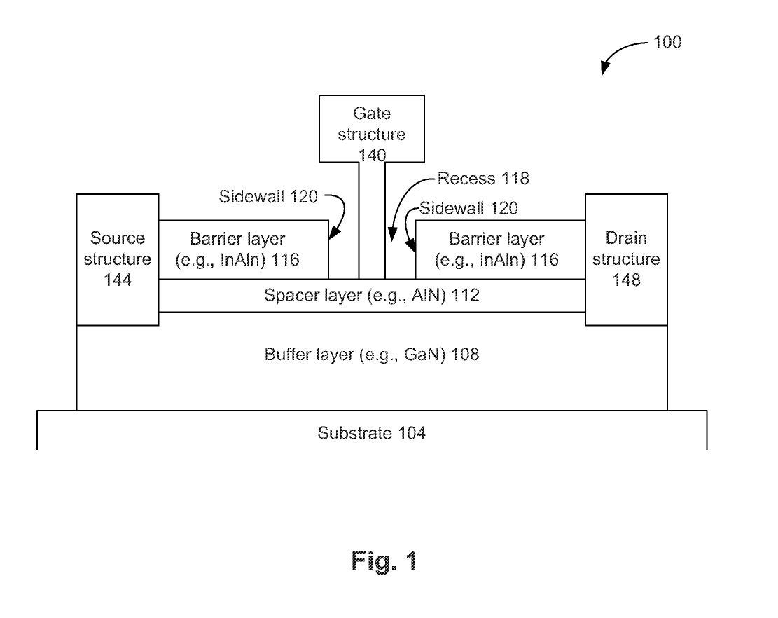

FIG. 1 schematically illustrates a cross-sectional view of a semiconductor device 100, in accordance with various embodiments of the present disclosure. In various embodiments, the semiconductor device 100 may be, for example, a HEMT (e.g., an enhancement mode HMET).

The semiconductor device 100 (hereinafter also referred to as “device 100”) may be formed on a substrate 104. In various embodiments, the substrate 104 may be of an appropriate material, e.g., Silicon Carbide. The device 100 includes a buffer layer 108 formed on the substrate 104. The buffer layer 108 may comprise, for example, Gallium Nitride (GaN), although any other material may also be used to form the buffer layer 108. The buffer layer 108 may provide an appropriate crystal structure transition between the substrate 104 and other components of the device 100, thereby acting as a buffer or isolation layer between the substrate 104 and other components of the device 100. The buffer layer 108 may be 1-2 micrometers (μm) thick, although in various other embodiments, the buffer layer 108 may be of any other thickness.

In various embodiments, the device 100 also includes a spacer layer 112 formed on the buffer layer 108. The spacer layer 112 may be formed only on a portion of a topside of the buffer layer 108, as illustrated in FIG. 1. The spacer layer 112 may be formed of any appropriate material (e.g., an appropriate wide bandgap material suitable for a spacer layer), including, for example, Aluminum Nitride (AlN). In various embodiments, the spacer layer 112 may be 10-15 angstroms (Å) thick, although in various other embodiments, the spacer layer 112 may be of any other (e.g., 10-30 Å) thickness.

The device 100 also includes a barrier layer 116 formed on the spacer layer 112. The barrier layer 116 may be formed of any appropriate material (e.g., an appropriate wide bandgap material suitable for a barrier layer), including, for example, Indium Aluminum Nitride (InAlN). The barrier layer 112 may be relatively thicker than the spacer layer. In various embodiments, the barrier layer 112 may be 50-150 Å thick, although in various other embodiments, the barrier layer 116 may be of any other thickness.

In various embodiments, the buffer layer 108 may be of lower bandgap compared to the bandgaps of the spacer layer 112 and/or the barrier layer 116. The difference in bandgaps in various layers of the device 100 creates a heterojunction in the device 100.

In various embodiments, a recess 118 may be formed in the barrier layer 116. The barrier layer 116 around the recess 118 may form side walls 120. The recess 118 may penetrate the barrier layer 116, forming a through hole in the barrier layer 116, to expose at least a part of the spacer layer 112. Thus, the exposed part of the spacer layer 112 beneath the recess 118 may not have any barrier layer 116 on top. In various embodiments, the recess 118 may be formed by etching a part of the barrier layer 116. During the etching process (e.g., while the recess 118 is formed in the barrier layer 116), the spacer layer 112 may act as an etch stop layer.

The device 100 may also include a gate structure 140. In various embodiments, at least a part of the gate structure 140 may be disposed, through the recess 118, on the spacer layer 112. Thus, at least a part of the gate structure 140 may be in direct contact (e.g., direct physical and/or direct electrical contact) with the spacer layer 112. In various embodiments, the part of the gate structure 140 disposed through the recess 118 may not be in direct contact with the side walls 120 of the recess 118. The space between the part of the gate structure 140 disposed through the recess 118 and the sidewalls 120 may be left empty or may be filled with an appropriate material (e.g., an appropriate material that is different from the material of the barrier layer 116, the gate structure 140, and/or the spacer layer 112). In various embodiments, the gate structure 140 may not be in direct contact with the barrier layer 116.

The device 100 may also include a source structure 144 and a drain structure 148 formed on respective portions of the buffer layer 108. In various embodiments, the source structure 144 and the drain structure 148 may be in direct contact with the spacer layer 112 and the barrier layer 116, as illustrated in FIG. 1.

In various embodiments, during operation of the device 100, the spacer layer 112 and/or the buffer layer 108 under the gate structure 140 (and/or under the recess 118) may allow enhancement mode operation of the device 100, while maintaining relatively high current. Also, the source access area and the drain access area may allow relatively low access resistance. In various embodiments, forming the buffer layer 108, the spacer layer 112, and barrier layer 116 of device 100 with GaN, AN, and InAlN, respectively, and forming at least a part of the gate structure 140 inside the recess 118 and on the spacer layer 112 (as illustrated in FIG. 1) may allow enhancement mode operation of the device 100 with relatively superior (e.g., desirable) operating characteristics (e.g., as compared to conventional devices). For example, completely etching at least a part of the barrier layer 116 (e.g., in a region where recess 118 is formed) and forming the gate structure 140 such that the gate structure 140 is in direct contact with the spacer layer 112 may result in a positive threshold voltage in the device 100, thereby allowing enhancement mode operation of the device 100.

For example, in various embodiments, the device 100 of FIG. 1 (e.g., with specific dimensions of various layers) may have a pinch-off voltage of about +200 milli-volts (mV), a transconductance (e.g., a relatively high or a maximum transconductance) of about 890 milli-Siemens/millimeter (mS/mm), and a current density (e.g., a relatively high or a maximum current density) of about 2 Ampere/millimeter (A/mm). Thus, a relatively deep enhancement mode characteristic (e.g., with a relatively high pinch-off voltage of about +200 mV) may be achieved by the device 100 while maintaining relatively high transconductance (e.g., about 890 mS/mm) and relatively high current density (e.g., about 2 A/mm) values. In another example, the device 100 may achieve a pinch-off voltage of about +600 mV, with a transconductance (e.g., a relatively high or a maximum transconductance) of about 800 mS/mm and a current density (e.g., a relatively high or maximum current density) of about 1.9 A/mm. In various other embodiments, various other values of pinch-off voltage, transconductance, and/or current density may also be achieved. In various embodiments, the structure and dimensions of various layers of the device 100 may be varied to achieve various values of pinch-off voltage, transconductance and/or current density.

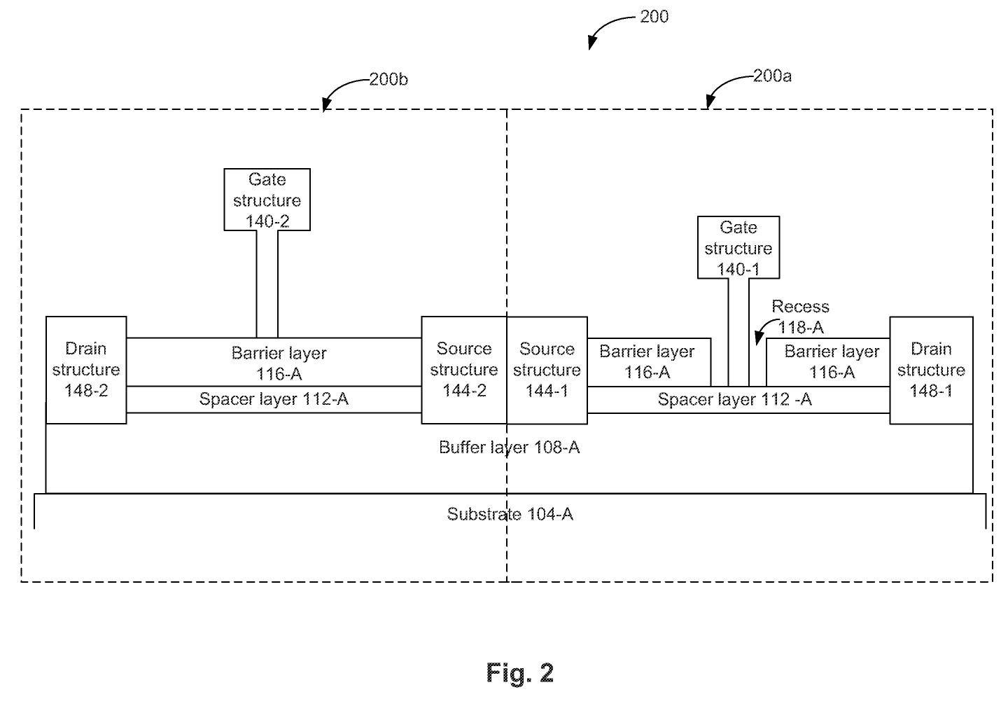

FIG. 2 schematically illustrates a cross-sectional view of another semiconductor device 200, in accordance with various embodiments of the present disclosure. The semiconductor device 200 (hereinafter also referred to as “device 200”) includes an enhancement mode HEMT 200a integrated with a depletion mode HEMT 200b. In FIG. 2, the enhancement mode HEMT 200a and the depletion mode HEMT 200b are illustrated in separate boxes (marked in dotted lines).

In various embodiments, the device 200 is formed by integrating both the enhancement mode HEMT 200a and the depletion mode HEMT 200b on a common substrate 104-A, which may comprise an appropriate substrate material, including, for example, Silicon Carbide.

In various embodiments, the enhancement mode HEMT 200a is at least in part similar to the device 100 of FIG. 1. For example, a buffer layer 108-A, a spacer layer 112-A, a barrier layer 116-A, a recess 118-A formed on the barrier layer 116-A, a gate structure 140-1 (which may have a part disposed, through the recess 118-A, on the spacer layer 112-A), a source structure 144-1 and a drain structure 148-1 of the enhancement mode HEMT 200a may be similar to the corresponding components of the device 100 of FIG. 1.

In various embodiments, the depletion mode HEMT 200b may share the buffer layer 108-A, the spacer layer 112-A, and the barrier layer 116-A with the enhancement mode HEMT 200a. That is, the enhancement mode HEMT 200a and the depletion mode HEMT 200b may have common substrate 104-A, common buffer layer 108-A, common spacer layer 112-A, and common barrier layer 116-A, although the inventive principles of the present disclosure may not be limited in this aspect. For example, although not illustrated in FIG. 2, in various embodiments, the enhancement mode HEMT 200a and the depletion mode HEMT 200b may be formed on separate substrates, and/or may have separate buffer layers, separate spacer layers, and/or separate barrier layers. Furthermore, depletion mode HEMT 200b may include a gate structure 140-2, a source structure 144-2 and a drain structure 148-2, which may be at least in part similar to the enhancement mode HEMT 200a. However, unlike the enhancement mode HEMT 200a, the barrier layer 116-A may not have a recess formed therethrough for the gate structure 140-2. Instead, the gate structure 140-2 of the depletion mode HEMT 200b may be formed on the barrier layer 116-2.

Although not illustrated in FIG. 2, in various embodiments, the source structure 144-1 of the enhancement mode HEMT 200a may be combined with the source structure 144-2 of the depletion mode HEMT 200b, so that there is a common source structure for both the enhancement mode HEMT 200a and the depletion mode HEMT 200b.

Similar to the device 100, in various embodiments, the buffer layer 108-A, spacer layer 112-A, and the barrier layer 116-A of device 200 may be formed using GaN, AN, and InAlN, respectively.

As the gate structure 140-1 in the enhancement mode HEMT 200a is formed on the spacer layer 112-A through recess 118-A, the resulting threshold voltage of the enhancement mode HEMT 200a is positive (similar to device 100 of FIG. 1), thereby resulting in enhancement mode operation of the enhancement mode HEMT 200a. On the other hand, as the gate structure 140-2 in the depletion mode HEMT 200a is formed on the barrier layer 116-A, the resulting threshold voltage of the depletion mode HEMT 200b is negative, thereby resulting in depletion mode operation of the depletion mode HEMT 200b.

In various embodiments, the enhancement mode HEMT 200a may exhibit characteristics that may be at least in part similar to the characteristics of the device 100 of FIG. 1, which has been previously discussed herein. In various embodiments, the depletion mode HEMT 200b may also exhibit relatively superior (e.g., desirable) operating characteristics (e.g., as compared to conventional depletion mode HEMT devices). For example, for specific dimensions of various layers, the depletion mode HEMT 200b may have a relatively high transconductance (e.g., a maximum transconductance) of about 600 mS/mm and a relatively high current density (e.g., a maximum current density) of greater than about 2 A/mm.

Because of the various characteristics (as previously discussed) of the device of FIG. 1, and the integrated enhancement mode and depletion mode HEMTs of FIG. 2, these transistors may be used in a variety of applications, including, for example, in low noise amplifiers operating at microwave and millimeter wave frequencies. These HEMTs may also be used as high power, high frequency transistors, as discrete transistors, and/or in integrated circuits, such as microwave monolithic integrated circuits (MMICs) used in space, military and commercial applications, mixed signal electronics, mixers, direct digital synthesizers, power digital to analog convertors, and/or the like.

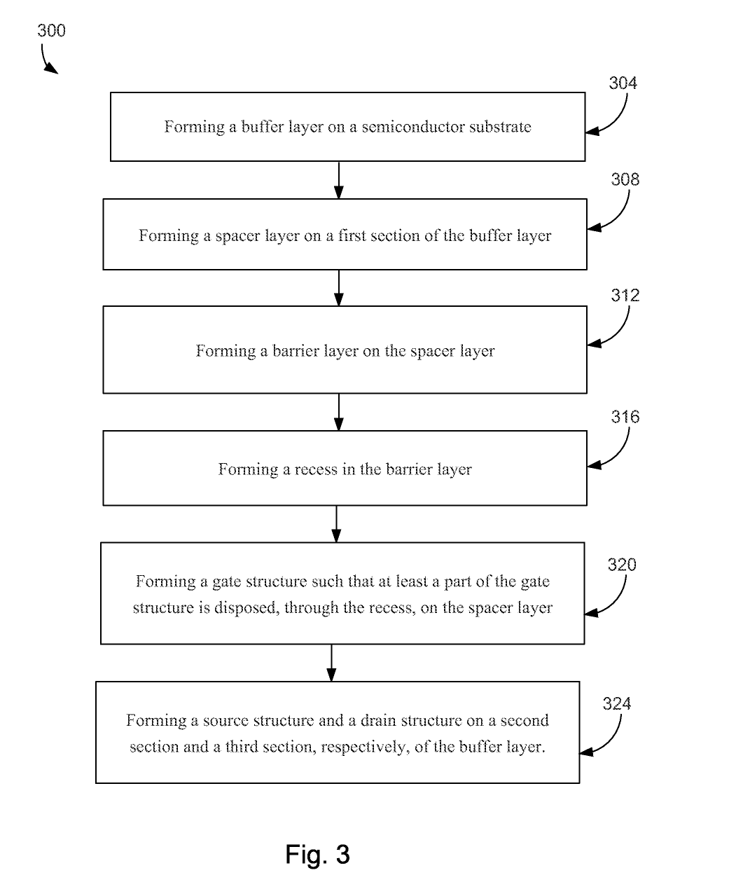

FIG. 3 illustrates a method 300 for fabricating a semiconductor device (e.g., an enhancement mode HEMT) on a semiconductor substrate, in accordance with various embodiments of the present disclosure. Referring to FIGS. 1 and 3, in various embodiments, the method 300 may include, at 304, forming a buffer layer (e.g., buffer layer 108) on a semiconductor substrate (e.g., substrate 104). In various embodiments, the buffer layer may comprise GaN, and the substrate may comprise Silicon Carbide.

The method 300 may further include, at 308, forming a spacer layer (e.g., spacer layer 112) on a first section (e.g., as illustrated in FIG. 1) of the buffer layer. In various embodiments, the spacer layer may comprise AN.

The method 300 may further include, at 312, forming a barrier layer (e.g., barrier layer 116) on the spacer layer. In various embodiments, the barrier layer may comprise InAlN.

At 316, a recess (e.g., recess 118) may be formed in the barrier layer. In various embodiments, the recess may form a through hole in the barrier layer.

The method 300 may further include, at 320, forming a gate structure (e.g., gate structure 140) such that at least a part of the gate structure is disposed, through the recess, on the spacer layer. In various embodiments, the recess may have side walls, and the gate structure may be formed such that at least the part of the gate structure, which is disposed through the recess, is not in contact with the side walls. In various embodiments, the gate structure may not be in contact with the barrier layer. In various embodiments, the gate structure may be in direct contact with the spacer layer.

The method 300 may further include, at 324, forming a source structure (e.g., source structure 144) and a drain structure (e.g., drain structure 148) on a second section and a third section, respectively, of the buffer layer (e.g., as illustrated in FIG. 1). In various embodiments, the source structure may be in direct contact with the spacer layer and the barrier layer, and the drain structure may be in direct contact with the spacer layer and the barrier layer, as illustrated in FIG. 1.

In various embodiments, operations at block 324 (e.g., formation of the source and drain structure) may be carried out before, during, or after one or more other operations of the method 300. For example, operations at block 324 may be carried out before, during, or after one or more other operations of blocks 316 and/or 320 (e.g., formation of the recess layer and/or the gate structure).

Although the present disclosure has been described in terms of the above-illustrated embodiments, it will be appreciated by those of ordinary skill in the art that a wide variety of alternate and/or equivalent implementations calculated to achieve the same purposes may be substituted for the specific embodiments shown and described without departing from the scope of the present disclosure. Those with skill in the art will readily appreciate that the teachings of the present disclosure may be implemented in a wide variety of embodiments. This description is intended to be regarded as illustrative instead of restrictive.

What is claimed is:

1. A method of fabricating a semiconductor device on a semiconductor substrate, the method comprising:
forming a buffer layer on the semiconductor substrate;
forming an Aluminum Nitride spacer layer on the buffer layer;
forming an Indium Aluminum Nitride barrier layer on the Aluminum Nitride spacer layer;
forming a recess in the Indium Aluminum Nitride barrier layer; and
forming a gate structure such that at least a part of the gate structure is disposed, through the recess, on the Aluminum Nitride spacer layer.

2. The method of claim 1, wherein the buffer layer comprises Gallium Nitride.

3. The method of claim 1, wherein the recess has side walls, and wherein forming the gate structure further comprises:
forming the gate structure such that at least the part of the gate structure, which is disposed through the recess, is not in contact with the side walls.

4. The method of claim 1, wherein forming the gate structure further comprises forming the gate structure such that the gate structure is not in contact with the Indium Aluminum Nitride barrier layer.

5. The method of claim 1, further comprising:
forming a source structure and a drain structure on the buffer layer.

6. The method of claim 5, wherein the source structure is in direct contact with the Aluminum Nitride spacer layer and the Indium Aluminum Nitride barrier layer, and wherein the drain structure is in direct contact with the Aluminum Nitride spacer layer and the Indium Aluminum Nitride barrier layer.

7. The method of claim 1, wherein the semiconductor device comprises an enhancement mode high electron mobility transistor (HEMT).

8. The method of claim 7, wherein the method further comprises:
forming a depletion mode HEMT such that the depletion mode HEMT is integrated with the enhancement mode HEMT on the semiconductor substrate.

9. The method of claim 8, wherein the gate structure is a first gate structure, wherein forming the depletion mode HEMT further comprises:
forming a second gate structure on the Indium Aluminum Nitride barrier layer.

10. The method of claim 9, further comprising:
forming a first source structure and a first drain structure on the buffer layer, wherein the enhancement mode HEMT comprises the first source structure, the first drain structure, and the first gate structure; and
forming a second source structure and a second drain structure on the buffer layer, wherein the depletion mode HEMT comprises the second source structure, the second drain structure, and the second gate structure.

11. The method of claim 10, further comprising:
integrating the first source structure with the second source structure.

12. A high electron mobility transistor (HEMT) comprising:
a semiconductor substrate;
a Gallium Nitride (GaN) layer formed on the semiconductor substrate;
an Aluminum Nitride (AlN) layer formed on the GaN layer;
an Indium Aluminum Nitride (InAlN) layer formed on the AlN layer, wherein the InAlN layer has a recess that forms a through hole in the InAlN layer; and
a gate structure, wherein at least a part of the gate structure is disposed, through the recess, on the AIN layer.

13. The HEMT of claim 12, wherein the recess has sidewalls, and wherein the part of the gate structure, which is disposed through the recess, is not in contact with the side walls.

14. The HEMT of claim 12, further comprising:
a source structure formed on the GaN layer; and
a drain structure on the GaN layer.

15. The HEMT of claim 12, wherein the semiconductor substrate comprises Silicon Carbide.

16. The HEMT of claim 12, wherein the HEMT comprises an enhancement mode HEMT, and wherein the enhancement mode HEMT is integrated with a depletion mode HEMT, the depletion mode HEMT comprising:
a second gate structure formed on the InAlN layer.

17. A semiconductor device comprising:
an enhancement mode high electron mobility transistor (HEMT) that includes:
an Indium Aluminum Nitride barrier layer formed on an Aluminum Nitride spacer layer, wherein the Indium Aluminum Nitride barrier layer has a recess; and
a first gate structure disposed at least in part through the recess, such that the first gate structure is in direct contact with the Aluminum Nitride spacer layer; and
a depletion mode HEMT that includes:
a second gate structure disposed on the Indium Aluminum Nitride barrier layer.

18. The semiconductor device of claim 17, wherein the first gate structure is not in direct contact with the Indium Aluminum Nitride barrier layer.

19. The semiconductor device of claim 17, wherein the enhancement mode HEMT and the depletion mode HEMT are integrated such that:
a source structure of the enhancement mode HEMT is adjacent to, or integrated with a source structure of the depletion mode HEMT.

20. The semiconductor device of claim 17, further comprising:
a Gallium Nitride buffer layer on which the Aluminum Nitride spacer layer is formed.
